(19) United States
(12) Patent Application Publication
(10) Pub. No.: US 2023/0317431 A1
(43) Pub. Date: Oct. 5, 2023

(54) JOINED STRUCTURE

(71) Applicant: NGK Insulators, Ltd., Nagoya-City (JP)

(72) Inventors: Yutaka UNNO, Handa-City (JP); Mikiya TADAKI, Santa Clara, CA (US); Takuya YOKONO, Komaki-City (JP)

(73) Assignee: NGK Insulators, Ltd., Nagoya-City (JP)

(21) Appl. No.: 18/171,803

(22) Filed: Feb. 21, 2023

(30) Foreign Application Priority Data
Mar. 31, 2022 (JP) 2022-058543

(51) Int. Cl. H01J 37/32

(52) U.S. Cl. CPC H01J 37/32715

(57) ABSTRACT

A joined structure includes: a ceramic member having a wafer placement surface; an embedded electrode that is embedded in the ceramic member and has a shape extending along the wafer placement surface; a metallic connection member embedded in a surface of the ceramic member that is opposite to the wafer-placement surface so as to reach the embedded electrode; and a metallic external energizing member joined to a surface of the connection member that is exposed to the outside with a joint layer interposed therebetween. The connection member has an arithmetic mean surface roughness Ra of 6 to 16 μm.

### BACKGROUND OF THE INVENTION

### 1. Field of the Invention

The present invention relates to a joined structure.

### 2. Description of the Related Art

A joined structure including a ceramic member, an electrode embedded in the ceramic member, a connection member embedded in the ceramic member so as to reach the electrode, and an external energizing member joined to the connection member with a joint layer interposed therebetween is a known art. For example, PTL 1 discloses a ceramic heater 610 shown in FIG. 6. This ceramic heater 610 includes a ceramic member 612 with a heater element 614 embedded therein. In the ceramic member 612, a bottomed cylindrical hole 612c is formed in a surface 612b opposite to a wafer placement surface 612a of the ceramic member 612. In the ceramic member 612, a circular columnar connection member 616 is embedded in the bottom surface of the hole 612c so as to reach the heater element 614. An external energizing member 618 is joined to a surface of the connection member 616 that is exposed to the outside with a joint layer 620 interposed therebetween. This ceramic heater 610 is used to perform CVD film formation or etching on a wafer using plasma.

### CITATION LIST

### Patent Literature

[PTL 1] International Publication No. WO2015/198892

### SUMMARY OF THE INVENTION

However, the ceramic heater 610 has the following problem. When thermal expansion of the connection member 616 due to an increase in plasma power or heater power occurs repeatedly and the external energizing member 618 is overloaded, the external energizing member 618 together with the connection member 616 falls out of the ceramic member 612.

The present invention has been made to solve the foregoing problem, and it is a main object to prevent the connection member from easily falling out of the ceramic member.

A joined structure of the present invention includes: a ceramic member having a wafer placement surface; an embedded electrode that is embedded in the ceramic member and has a shape extending along the wafer placement surface; a metallic connection member embedded in a surface of the ceramic member that is opposite to the wafer-placement surface so as to reach the embedded electrode; and a metallic external energizing member joined to a surface of the connection member that is exposed to the outside with a joint layer interposed therebetween, wherein the connection member has an arithmetic mean surface roughness Ra of 6 to 16 μm.

In this joined structure, the connection member has an arithmetic mean surface roughness Ra of 6 to 16 μm. Therefore, even when the external energizing member is overloaded, the anchoring effect of the connection member can prevent the external energizing member together with the connection member from easily falling out of the ceramic member.

In the joined structure of the present invention, the connection member may include particles having an average particle diameter of 4 to 8 μm. In this case, the anchoring effect is stronger than that when the average particle diameter is less than 4 μm. The average particle diameter of the particles included in the connection member is not the average particle diameter of a raw material powder used to produce the connection member but is the average particle diameter of the particles forming the connection member itself.

In the joined structure of the present invention, the connection member may be formed of a metallic porous body having a porosity of 5 to 20%. In this case, the connection member having an arithmetic mean surface roughness Ra of 6 to 16 μm can be relatively easily produced. Such a connection member is produced, for example, by powder metallurgy using a metal powder having an average particle diameter of 4 to 8 μm.

In the joined structure of the present invention, the ceramic member may be made of aluminum nitride, and the connection member may be made of Mo, W, or a Mo—W-based alloy. In this case, the ceramic member is unlikely to be cracked. This is because the difference in coefficient of thermal expansion between the ceramic member and the connection member is small.

In the joined structure of the present invention, the external energizing member may have a proof tensile load of 120 kgf or more. A large load is often applied to the external energizing member during production or use of the joined structure, and the significance of the external energizing member having a proof tensile load of 120 kgf or more is high.

### BRIEF DESCRIPTION OF THE DRAWINGS

FIG. 1 is a cross-sectional view of a main portion of a wafer placement table 10.

FIG. 2 is a perspective view of a connection member 16.

FIG. 3 is an enlarged view of portion A in FIG. 1.

FIGS. 4A to 4C are illustrations showing a production process of the connection member 16.

FIGS. 5A to 5D are illustrations showing a production process of the wafer placement table 10.

FIG. 6 is a cross-sectional view of a main portion of a ceramic heater 610.

### DETAILED DESCRIPTION OF THE INVENTION

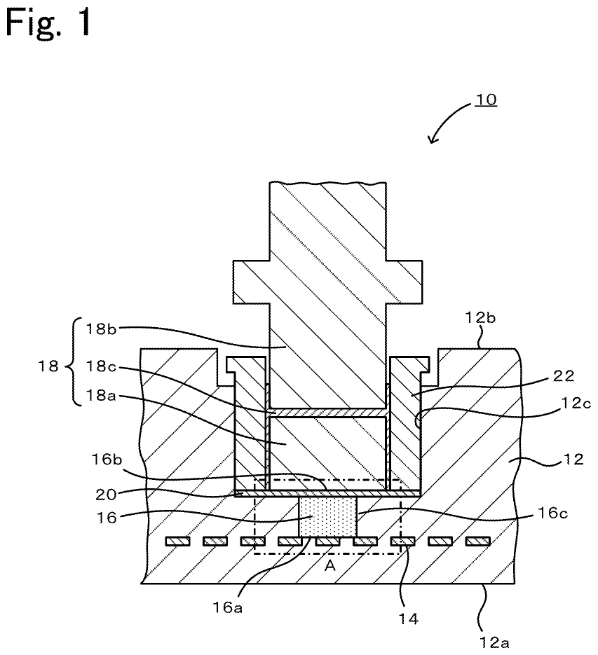

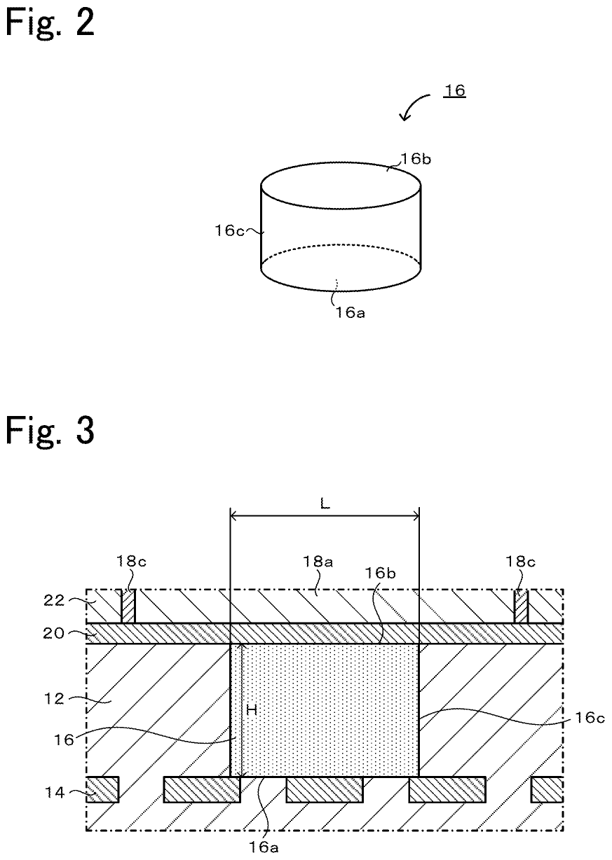

Next, a wafer placement table 10 in one preferred embodiment of the joined structure of the present invention will be described. FIG. 1 is a cross-sectional view of a main portion of the wafer placement table 10, and FIG. 2 is a perspective view of a connection member 16. FIG. 3 is an enlarged view of portion A in FIG. 1. In the present specification, “to” indicating a numerical range is used to mean that numerical values before and after it are included as lower and upper limits, respectively.

The wafer placement table 10 (corresponding to the joined structure of the present invention) is used to place a wafer to be subjected to etching, CVD, etc. using plasma and is installed in an unillustrated vacuum chamber. The wafer placement table 10 includes a ceramic member 12, an RF electrode (corresponding to the embedded electrode of the invention) 14, the connection member 16, an external energizing member 18, and a guide member 22.

The ceramic member 12 is formed to have a disk shape, and one of its surfaces is a wafer placement surface 12a on which a wafer is to be placed. In FIG. 1, the wafer placement surface 12a is facing down. However, when the wafer placement table 10 is actually used, the wafer placement table 10 is placed such as the wafer placement surface 12a faces up. Preferably, the ceramic member 12 is made of, for example, aluminum nitride. The ceramic member 12 has a bottomed cylindrical hole 12c formed in a surface 12b opposite to the wafer placement surface 12a. The ceramic member 12 may have, for example, a diameter of 150 to 500 mm and a thickness of 10 to 30 mm. The hole 12c may have, for example, a diameter of 5 to 15 mm and a depth of 5 to 25 mm.

The RF electrode 14 is an electrode embedded in the ceramic member 12 and is a member having a shape extending along the wafer placement surface 12a. In this case, the RF electrode 14 is a circular metal mesh. The material of the RF electrode 14 is preferably, for example, tungsten, molybdenum, tantalum, platinum, or an alloy thereof. The metal mesh may have, for example, a wire diameter of 0.1 to 1.0 mm and may include 10 to 100 wires per inch. The RF electrode 14 may be formed by printing.

The connection member 16 is a metal member embedded in the bottom surface of the hole 12c of the ceramic member 12 so as to reach the RF electrode 14. The connection member 16 is a circular columnar member having a first surface 16a, a second surface 16b, and a third surface 16c. The first surface 16a is a surface on the RF electrode 14 side and is a circular surface. The second surface 16b is a surface on a joint layer 20 side and is a circular surface with the same shape as the first surface 16a. The second surface 16b is exposed in the hole 12c and is flush with the bottom surface of the hole 12c. The third surface 16c is the side surface of the circular column. The connection member 16 is made of a porous metal material. Examples of the metal used include Mo, W, and Mo—W-based alloys.

The diameter L of the first surface 16a and the second surface 16b of the connection member 16 is preferably 1 to 5 mm and more preferably 2.5 to 3.5 mm. The height H of the connection member 16 is preferably 1 to 5 mm and more preferably 1 to 2 mm. The arithmetic mean roughness Ra of the first surface 16a, the second surface 16b, and the third surface 16c is preferably 6 to 16 μm. The connection member 16 includes metal particles having an average particle diameter of preferably 4 to 8 μm. The porosity of the porous metal material forming the connection member 16 is preferably 5 to 20%.

The external energizing member 18 includes: a first portion 18a joined to the connection member 16 with a joint layer 20 interposed therebetween; and a second portion 18b joined to a surface of the first portion 18a that is opposite to the joint surface joined to the connection member 16 with an intermediate joint portion 18c interposed therebetween. The second portion 18b is made of a highly oxidation-resistant metal, in consideration of use in a plasma atmosphere or a corrosive gas atmosphere. However, the highly oxidation-resistant metal generally has a large coefficient of thermal expansion. Therefore, when the second portion 18b is joined directly to the connection member 16, the joint strength between them is low because of the difference in thermal expansion between them. Thus, the second portion 18b is joined to the connection member 16 with the first portion 18a interposed therebetween which is made of a metal having a coefficient of thermal expansion close to the coefficient of thermal expansion of the connection member 16. Preferred examples of the material of the second portion 18b include pure nickel, nickel-based heat-resistant alloys, gold, platinum, silver, and alloys thereof. Preferred examples of the material of the first portion 18a include molybdenum, tungsten, molybdenum-tungsten alloys, tungsten-copper-nickel alloys, and Kovar. The joint layer 20 is formed using a brazing material. The brazing material is preferably a metal brazing material and preferably, for example, a Au—Ni brazing material, an Al brazing material, or a Ag brazing material. The joint layer 20 joins the second surface 16b of the connection member 16 to an end surface of the first portion 18a. The intermediate joint portion 18c of the external energizing member 18 joins the first portion 18a to the second portion 18b, fills the gap between the inner circumferential surface of the guide member 22 and the entire outer circumferential surface of the first portion 18a or a part thereof, and connects the inner circumferential surface of the guide member 22 to part of the outer circumferential surface of the second portion 18b. Therefore, the intermediate joint portion 18c prevents the first portion 18a from coming into contact with the surrounding atmosphere. The intermediate joint portion 18c can be formed using the same material as the material of the joint layer 20. The first portion 18a may have a diameter of 3 to 6 mm and a height of 2 to 5 mm, and the second portion 18b may have a diameter of 3 to 6 mm and any height.

The guide member 22 is a hollow cylindrical member surrounding at least the first portion 18a of the external energizing member 18 and is made of a material that is more oxidation-resistant than the first portion 18a. The guide member 22 has an inner diameter larger than the outer diameter of the first portion 18a and the outer diameter of the second portion 18b (excluding its flange), has an outer diameter smaller than the diameter of the hole 12c, and has a height larger than the height of the first portion 18a. An end surface of the guide member 22 that faces the bottom surface of the hole 12c is joined to the connection member 16, the external energizing member 18, and the ceramic member 12 with the joint layer 20 therebetween. The material of the guide member 22 may be any of the materials exemplified as the material of the second portion 18b of the external energizing member 18. The end surface of the guide member 22 may be joined to the bottom surface of the hole 12c with the joint layer 20 therebetween as shown in FIG. 1 or may be spaced apart from the bottom surface of the hole 12c.

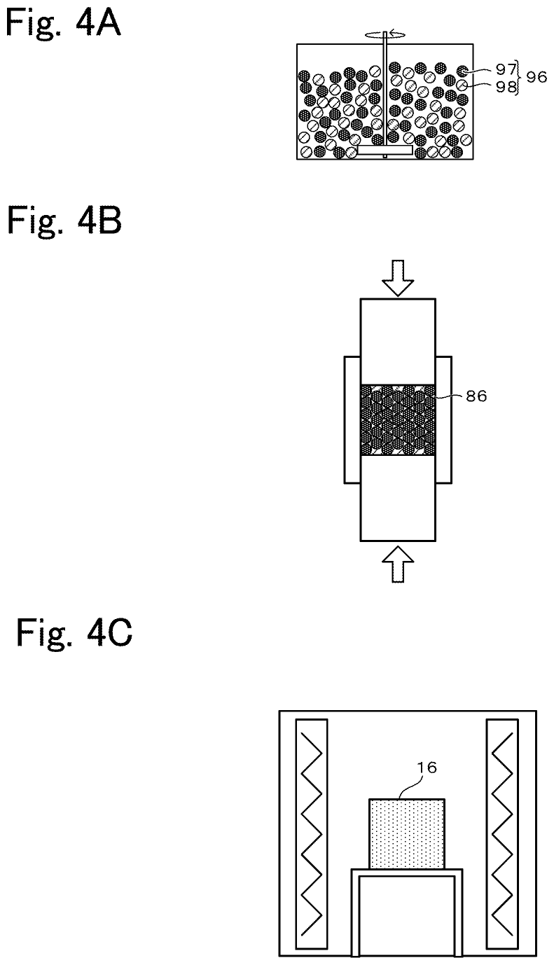

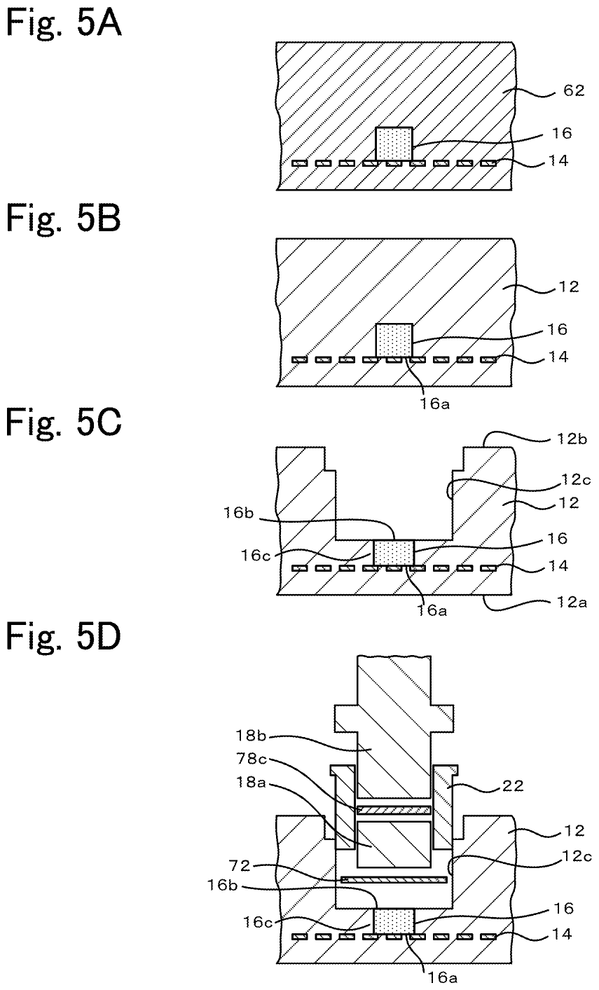

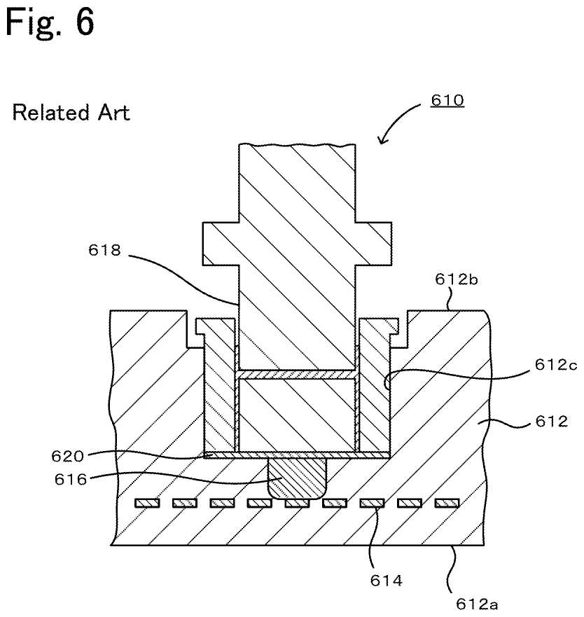

Next, a method for producing the wafer placement table 10 will be described using FIGS. 4A to 4C and 5A to 5D. First, the connection member 16 is prepared. The connection member 16 is produced, for example, by powder metallurgy as follows. Specifically, a metal powder 97 and a resin powder 98 are mixed. A mixture 96 is thereby obtained (FIG. 4A). Next, the mixture 96 is filled into a mold and compression-molded. A molded body 86 is thereby obtained (FIG. 4B). Next, the molded body 86 is heated to 400 to 500° C. for about 1 hour to burn off and remove the resin contained in the molded body 86. Then the resulting molded body 86 is heated to 1300 to 1800° C. for about 1 hour to sinter the metal powder 97. The connection member 16 made of the porous metal material is thereby obtained (FIG. 4C). A connection member 16 having the desired arithmetic mean roughness Ra, the desired average particle diameter, and the desired porosity can be obtained by appropriately changing the average particle diameter of the metal powder 97, the pressure, the temperature during heating, and the heating time. The average particle diameter of the particles forming the connection member 16 is substantially the same as the average particle diameter of the metal powder 97.

Next, a ceramic raw material powder is press-molded into a disk to produce a molded body 62 (FIG. 5A). The RF electrode 14 formed from a circular metal mesh and the connection member 16 have been embedded in the molded body 62. The molded body 62 is fired in a hot press furnace or an atmospheric pressure furnace and thereby sintered to form the ceramic member 12 (FIG. 5B). The ceramic member 12 obtained is then machined so as to have prescribed dimensions.

Then the surface 12b of the ceramic member 12 that is opposite to the wafer placement surface 12a is ground to form the bottomed cylindrical hole 12c (FIG. 5C). In this case, the surface 12b is ground such that the second surface 16b of the connection member 16 is exposed in the hole 12c and the bottom surface of the hole 12c and the second surface 16b of the connection member 16 are flush with each other.

Next, a brazing material 72 that later becomes the joint layer 20 is placed on the bottom surface of the hole 12c. Then the first portion 18a of the external energizing member 18, a brazing material 78c that later becomes the intermediate joint portion 18c, the guide member 22, and the second portion 18b of the external energizing member 18 are stacked in this order on the brazing material 72 to thereby obtain a stacked body (FIG. 5D). The stacked body is heated under non-oxidizing conditions to melt the brazing materials 72 and 78c, and the molten brazing materials 72 and 78c are then solidified to obtain the wafer placement table 10 shown in FIG. 1. The non-oxidizing conditions mean a vacuum atmosphere or a non-oxidizing atmosphere (e.g. an inert atmosphere such as an argon atmosphere or a nitrogen atmosphere).

In the wafer placement table 10 described above, the connection member 16 has an arithmetic mean surface roughness Ra of 6 to 16 μm. Therefore, even when the external energizing member 18 is overloaded, the anchoring effect can prevent the external energizing member 18 together with the connection member 16 from easily falling out of the ceramic member 12.

In the wafer placement table 10, the particles included in the connection member 16 have an average particle diameter of preferably 4 to 8 μm. In this case, the anchoring effect is stronger than that when the average particle diameter is less than 4 μm.

Moreover, in the wafer placement table 10, it is preferable that the metallic porous body forming the connection member 16 has a porosity of 5 to 20%. In this case, the connection member having an arithmetic mean surface roughness Ra of 6 to 16 μm can be relatively easily produced.

Moreover, in the wafer placement table 10, the ceramic member 12 is made of aluminum nitride, and the connection member 16 is made of Mo, W, or a Mo—W-based alloy. Therefore, the ceramic member 12 is unlikely to be cracked. This is because the difference in coefficient of thermal expansion between the ceramic member 12 and the connection member 16 is small.

The present invention is not limited to the embodiment described above. It will be appreciated that the present invention can be implemented in various forms so long as they fall within the technical scope of the invention. The present invention is suitable for a structure including a connection member 16 that is disposed between an electrode embedded in a ceramic member 12 and an external energizing member 18 and that is embedded in the ceramic member 12.

For example, in the embodiment described above, the connection member 16 is made of the porous metal material, but this is not a limitation. In the embodiment described above, the connection member 16 may be made of a dense metal material.

In the embodiment described above, the connection member 16 may include a corner portion disposed between the first surface 16a and the third surface 16c and having a prescribed radius of curvature R. This can prevent the occurrence of cracking in a portion of the ceramic member 12 that is near the corner portion. In this case, the radius of curvature R is preferably 0.3 to 1.5 mm.

In the embodiment described above, the RF electrode 14 is embedded in the ceramic member 12. However, an electrostatic electrode or a heater element may be embedded in addition to or in place of the RF electrode 14. Both the electrostatic electrode and the heater element may be embedded.

In the wafer placement table 10 in the above described embodiment, a hollow cylindrical shaft made of the same material as the material of the ceramic member 12 may be disposed on the surface 12b opposite to the wafer placement surface 12a so as to be integrated with the ceramic member 12. In this case, the external energizing member 18 is disposed inside the hollow portion of the shaft. To produce the shaft, for example, a ceramic raw material powder is molded by CIP using a mold, and the molded product is fired in an atmospheric pressure furnace. After the firing, the fired product is machined so as to have prescribed dimensions. To integrate the shaft with the ceramic member 12, for example, an end surface of the shaft is brought into abutment against the surface 12b of the ceramic member 12, and the shaft and the ceramic member 12 are heated to a prescribed temperature to join them together.

In the embodiment described above, the flange of the second portion 18b of the external energizing member 18 and an end surface of the guide member 22 are not joined together. However, they may be brought close to each other with a joint layer (made of, for example, the same material as the material of the joint layer 20) interposed therebetween and joined together with the joint layer therebetween.

### EXAMPLES

Examples of the present invention will be described. Among the following Experimental Examples 1 to 9, Experimental Examples 1 to 5 correspond to Examples of the present invention, and Experimental Examples 6 to 9 correspond to Comparative Examples. It should be noted that the following Examples do not at all limit the present invention.

### Experimental Example 1

### 1. Preparation of Connection Member 16

### (1) Preparation of Connection Member 16

The connection member 16 was produced according to the production procedure in FIGS. 4A to 4C. Specifically, a mixture 96 was produced by mixing 91% by mass of a Mo powder, as the metal powder 97, having an average particle diameter of 4 μm and 9% by mass of the resin powder 98. Next, the mixture 96 produced was filled into a mold and subjected to compression molding to produce a circular columnar molded body 86. Then the molded body 86 was heated to 500° C. for 1 hour to burn off and remove the resin contained in the molded body 86. Then the resulting molded body 86 was heated to 1800° C. for one hour to sinter the metal powder 97 to thereby obtain a circular columnar connection member 16. The diameters of the upper and lower surfaces of the obtained connection member 16 were 3 mm, and the height of the connection member 16 was 1.5 mm.

### (2) Measurement of Arithmetic Mean Surface Roughness Ra

Values measured using an optical interferometer by a method according to JIS B 0601:2013 were used as the arithmetic mean roughnesses Ra of the surfaces of the connection member 16 (the first surface 16a, the second surface 16b, and the third surface 16c). The arithmetic mean surface roughness Ra was 6 μm.

### (3) Measurement of Average Particle Diameter

The average particle diameter of the particles included in the connection member 16 was measured as follows. Specifically, first, the connection member 16 was cut, and an SEM image of the cross section (magnification: 3000×) was obtained. Then straight lines were drawn on the image. The lengths of 40 line segments crossing particles were measured, and the average value was computed and used as the average particle diameter. The results showed that the average particle diameter of the particles included in the connection member 16 was 4 μm.

### (4) Measurement of Porosity

The porosity of the connection member 16 was measured as follows. Specifically, first, a cross section of the connection member 16 was embedded in a resin and polished to prepare a sample for observation. Next, an SEM image of the cross section was taken (magnification: 1000×). Next, the image obtained was subjected to image analysis, and a threshold value was determined by a discriminant analysis method (Otsu's binarization) using a brightness distribution obtained from the brightness data of pixels in the image. Using the determined threshold value, the pixels in the image were binarized and classified into object portions and pore portions, and the area of the object portions and the area of the pore portions were computed. Then the ratio of the area of the pore portions to the total area (the total area of the object portions and the pore portions) was computed as a porosity. The results showed that the porosity of the connection member 16 was 5%.

### 2. Production of Wafer Placement Table

### (1) Production of Molded Body 62

Three sample wafer placement tables 10 were produced according to the production procedure in FIGS. 5A to 5D. First, the RF electrode 14 and the connection member 16 were embedded in a powder mixture obtained by mixing an aluminum nitride powder and a sintering aid, and uniaxial compression molding was performed to produce a molded body 62. The RF electrode 14 used was a molybdenum-made wire mesh. The wire mesh used was formed from molybdenum wires having a diameter of 0.12 mm and woven at a density of 50 wires per inch.

### (2) Firing

Next, the molded body 62 was placed in a mold, sealed in a carbon foil, and fired by hot pressing to thereby obtain a ceramic member 12. After the firing, the ceramic member 12 was machined to a diameter of 200 mm and a thickness of 8 mm.

### (3) Formation of Hole 12c

Next, a bottomed cylindrical hole 12c was formed in the surface 12b of the ceramic member 12 opposite to the wafer placement surface 12a using a machining center. The hole 12c had a diameter of 9 mm (aperture diameter: 12 mm) and a depth of 4.5 mm. In this case, the ceramic member 12 was machined such that the second surface 16b of the connection member 16 was exposed in the hole 12c and that the bottom surface of the hole 12c and the second surface 16b of the connection member were flush with each other.

### (4) Joining of External Energizing Member 18

Next, the brazing material 72 composed of Au—Ni was placed on the bottom surface of the hole 12c, and the first portion 18a of the external energizing member 18, the brazing material 78c composed of Au—Ni, the guide member 22 made of nickel (purity: 99% or higher), and the second portion 18b of the external energizing member 18 were stacked on the brazing material 72 to thereby obtain a stacked body. The first portion 18a used was made of Kovar and had a diameter of 4 mm and a height of 3 mm, and the second portion 18b used was made of nickel (purity: 99% or higher) and had a diameter of 4 mm (flange diameter: 8 mm) and a height of 60 mm. The stacked body was heated to 960 to 1100° C. in an inert atmosphere for 10 minutes to thereby obtain the wafer placement table 10 shown in FIG. 1.

### Experimental Examples 2 to 9

In each of Experimental Examples 2 to 9, three wafer placement tables 10 were produced in the same manner as in Experimental Example 1 except that the connection member 16 was prepared such that the values of the arithmetic mean surface roughness Ra, the average particle diameter, and the porosity were as shown in Table 1.

TABLE 1

| | Arithmetic | Average | | | Proof | |
|---|---|---|---|---|---|---|
| | mean surface | particle | | | tensile | |
| | roughness Ra | diameter | Porosity | | load | |
| | [μm] | [μm] | [%] | Cracking | [Kgf] | Evaluation |
| Experimental | 6 | 4 | 5 | Not | 120 | OK |
| Example 1 | | | | occurred | | |
| Experimental | 9 | 5 | 9 | Not | 120 | OK |
| Example 2 | | | | occurred | | |
| Experimental | 13 | 7 | 11 | Not | 120 | OK |
| Example 3 | | | | occurred | | |
| Experimental | 15 | 7 | 17 | Not | 120 | OK |
| Example 4 | | | | occurred | | |
| Experimental | 16 | 8 | 20 | Not | 120 | OK |
| Example 5 | | | | occurred | | |
| Experimental | 1.0 | 3 | 0 | Not | 77 to 95 | NG |
| Example 6 | | | | occurred | | |
| Experimental | 1.3 | 3 | 2 | Not | 74 to 97 | NG |
| Example 7 | | | | occurred | | |
| Experimental | 4 | 3 | 3 | Not | 86 to 110 | NG |
| Example 8 | | | | occurred | | |
| Experimental | 20 | 10 | 24 | Occurred | 42 to 80 | NG |
| Example 9 | | | | | | |

### Evaluation of Wafer Placement Table

### (1) Occurrence of Breakage During Production

The occurrence of breakage of the wafer placement tables 10 produced in Experimental Examples 1 to 9 during production was examined. For each Experimental Example, the occurrence of breakage in each of the three wafer placement tables 10 was examined. Specifically, the occurrence of cracking in the ceramic member 12 immediately after the production of the ceramic member 12 by sintering of the molded body 62 was examined. A cracked ceramic member 12 was judged to be damaged during production.

### (2) Proof Tensile Load

The proof tensile load of each of the wafer placement tables 10 produced in Experimental Examples 1 to 9 was examined. For each Experimental Example, the proof tensile load of each of the three wafer placement tables 10 was examined. The proof tensile load was examined as follows. Specifically, a male thread was formed at a free end of the external energizing member 18. A female thread of a circular columnar connection jig was screwed onto the male thread, and then the resulting wafer placement table 10 was left to stand at 700° C. in an oxygen atmosphere for 800 hours. Then the wafer placement surface 12a of the ceramic member 12 was fixed to a work placement surface. With this state maintained, the connection jig was pulled using a tensile tester while a vertical load was changed from 1 to 120 kgf. When the connection member did not come off the ceramic member 12 even when the pulling load was 120 kgf, the proof tensile load was judged to be 120 kgf or more. Otherwise, a pulling load at which the connection member 16 together with the external energizing member 18 came off the ceramic member 12 was used as the proof tensile load.

### (3) Judgement

The occurrence of breakage during production and the proof tensile load were examined using the methods described above. When no breakage during production was found and the proof tensile load was 120 kgf or more, the ceramic member 12 was judged OK. However, when breakage during production was found or the proof tensile load was less than 120 kgf, the ceramic member 12 was judged NG (NG means “no good”).

In Experimental Examples 1 to 5 (three wafer placement tables 10 for each Experimental Example) in which the arithmetic mean surface roughness Ra of the connection member 16 was 6 to 16 μm, no breakage during production was found, and the proof tensile load was 120 kgf or more. In Experimental Examples 1 to 5, the average particle diameter of the particles included in the connection member 16 was 4 to 8 μm.

However, in Experimental Examples 6 to 8 in which the arithmetic mean surface roughness Ra was less than 6 μm, although no breakage during production was found, the proof tensile load was less than 120 kgf. In Experimental Examples 6 to 8, the average particle diameter of the particles included in the connection member 16 was 3 μm, and the porosity of the connection member 16 was less than 5%. In Experimental Example 9 in which the arithmetic mean surface roughness Ra was larger than 16 μm, breakage during production was found, and the proof tensile load was less than 120 kgf. In Experimental Example 9, the average particle diameter of the particles included in the connection member 16 was 10 μm, and the porosity of the connection member 16 was 24%. In Experimental Example 6, “to” is used to represent that the proof tensile load is in a prescribed numerical range. This is because the proof tensile loads of the three wafer placement tables produced in Experimental Example 6 were different. The same applies to Experimental Examples 7 to 9.

The present application claims priority from Japanese Patent Application No. 2022-058543 filed on Mar. 31, 2022, the entire contents of which are incorporated herein by reference.

What is claimed is:

1. A joined structure comprising:
a ceramic member having a wafer placement surface;
an embedded electrode that is embedded in the ceramic member and has a shape extending along the wafer placement surface;
a metallic connection member embedded in a surface of the ceramic member that is opposite to the wafer-placement surface so as to reach the embedded electrode; and
a metallic external energizing member joined to a surface of the connection member that is exposed to the outside with a joint layer interposed therebetween,
wherein the connection member has an arithmetic mean surface roughness Ra of 6 to 16 μm.

2. The joined structure according to claim 1, wherein the connection member includes particles having an average particle diameter of 4 to 8 μm.

3. The joined structure according to claim 1, wherein the connection member is formed of a metallic porous body having a porosity of 5 to 20%.

4. The joined structure according to claim 1, wherein the ceramic member is made of aluminum nitride, and
wherein the connection member is made of Mo, W, or a Mo—W-based alloy.

5. The joined structure according to claim 1, wherein the external energizing member has a proof tensile load of 120 kgf or more.
